(19) United States
(12) Patent Application Publication
(10) Pub. No.: US 2026/0333988 A1
(43) Pub. Date: Oct. 22, 2026

(54) DISPLAY PANEL AND DISPLAY APPARATUS

(71) Applicant: TIANMA ADVANCED DISPLAY TECHNOLOGY INSTITUTE (XIAMEN) CO., LTD., Xiamen (CN)

(72) Inventors: Lanshu YE, Xiamen (CN); Xiangzhao KONG, Xiamen (CN); Bo ZHOU, Xiamen (CN)

(21) Appl. No.: 19/690,507

(22) Filed: May 28, 2026

(30) Foreign Application Priority Data
Jan. 29, 2026 (CN) 202610124183.0

(51) Int. Cl. H10H 29/85; H10H 29/01; H10H 29/49

(52) U.S. Cl. CPC H10H 29/8582; H10H 29/012; H10H 29/49; H10H 29/8581

(57) ABSTRACT

A display panel includes an array substrate, and has a first region and a second region. The array substrate includes a substrate, a first-type conductive layer, and thermal insulation structures. The first-type conductive layer includes a first-type metal layer. A metal distribution ratio corresponding to the first region is P1, and a metal distribution ratio corresponding to the second region is P2, P1>P2, the metal distribution ratio is a ratio of a projection area of a portion of the first-type metal layer corresponding to a unit region on the substrate to an area of the unit region. The thermal insulation structures are located on a side of the first-type conductive layer away from the substrate and located in the first region, and the thermal insulation structures at least partially overlap the first-type metal layer in a direction perpendicular to a plane of the display panel.

### CROSS-REFERENCE TO RELATED DISCLOSURES

This application claims priority to Chinese Patent Application No. 202610124183.0, filed on Jan. 29, 2026, which is hereby incorporated by reference in its entirety.

### TECHNICAL FIELD

The present disclosure relates to the field of display technologies, and in particular, to a display panel and a display apparatus.

### BACKGROUND

In the related art, during the manufacturing process of a display panel, a process using laser irradiation to bond light-emitting devices to a substrate has gradually become one of the mainstream solutions. However, during the bonding of light-emitting devices, laser inevitably irradiates non-bonding regions, causing partial structures (such as metal layer structures) in the irradiated regions to generate heat, thereby leading to a temperature increase. When the temperature rises in certain regions inside the display panel, partial layer structures (such as organic layer structures) located in such regions tend to expand. Such expansion easily damages the integrity of device structures in these regions, thereby causing panel failure.

### SUMMARY

An aspect of the present disclosure provides a display panel. The display panel includes an array substrate, and has a first region and a second region. The array substrate includes a substrate, a first-type conductive layer, and thermal insulation structures. The first-type conductive layer includes a first-type metal layer. A metal distribution ratio corresponding to the first region is P1, and a metal distribution ratio corresponding to the second region is P2, where P1>P2, the metal distribution ratio is a ratio of a projection area of a portion of the first-type metal layer corresponding to a unit region on the substrate to an area of the unit region. The thermal insulation structures are located on a side of the first-type conductive layer away from the substrate and located in the first region, and the thermal insulation structures at least partially overlap the first-type metal layer in a direction perpendicular to a plane of the display panel.

Another aspect of the present disclosure provides a display apparatus. The display apparatus includes a display panel. The display panel includes an array substrate, and has a first region and a second region. The array substrate includes a substrate, a first-type conductive layer, and thermal insulation structures. The first-type conductive layer includes a first-type metal layer. A metal distribution ratio corresponding to the first region is P1, and a metal distribution ratio corresponding to the second region is P2, where P1>P2, the metal distribution ratio is a ratio of a projection area of a portion of the first-type metal layer corresponding to a unit region on the substrate to an area of the unit region. The thermal insulation structures are located on a side of the first-type conductive layer away from the substrate and located in the first region, and the thermal insulation structures at least partially overlap the first-type metal layer in a direction perpendicular to a plane of the display panel.

### BRIEF DESCRIPTION OF DRAWINGS

For a clearer understanding of the technical solutions of the embodiments of the present disclosure, the accompanying drawings required in the embodiments will be briefly introduced below. The drawings described below are merely some embodiments of the present disclosure. For those of ordinary skill in the art, other drawings may be obtained based on these drawings.

FIG. 1 is a schematic diagram of a partial structure of a display panel in the related art;

FIG. 2 is a top view of a partial structure of a display panel according to an embodiment of the present disclosure;

FIG. 3 is a cross-sectional view of the display panel shown in FIG. 2 along a section line AA′ according to an embodiment of the present disclosure;

FIG. 4 is a cross-sectional view of the display panel shown in FIG. 2 along a section line AA′ according to an embodiment of the present disclosure;

FIG. 5 is a top view of a first-type conductive layer distributed in a selected unit region according to an embodiment of the present disclosure;

FIG. 6 is a top view of a partial structure of a display panel according to an embodiment of the present disclosure;

FIG. 7 is a top view of a partial structure of a display panel according to an embodiment of the present disclosure;

FIG. 8 is a top view of a partial structure of a display panel according to an embodiment of the present disclosure;

FIG. 9 is a cross-sectional view of the display panel shown in FIG. 8 along a section line BB′ according to an embodiment of the present disclosure;

FIG. 10 is a top view of a partial structure of a display panel according to an embodiment of the present disclosure;

FIG. 11 is a cross-sectional view of the display panel shown in FIG. 10 along a section line CC′ according to an embodiment of the present disclosure;

FIG. 12 is a top view of a partial structure of a display panel according to an embodiment of the present disclosure;

FIG. 13 is a cross-sectional view of the display panel shown in FIG. 12 along a section line DD′ according to an embodiment of the present disclosure;

FIG. 14 is a top view of a partial structure of a display panel according to an embodiment of the present disclosure;

FIG. 15 is a top view of a partial structure of a display panel according to an embodiment of the present disclosure;

FIG. 16 is a top view of a partial structure of a display panel according to an embodiment of the present disclosure;

FIG. 17 is a cross-sectional view of the display panel shown in FIG. 15 along a section line EE′ according to an embodiment of the present disclosure;

FIG. 18 is a top view of a partial structure of a display panel according to an embodiment of the present disclosure;

FIG. 19 is a cross-sectional view of the display panel shown in FIG. 18 along a section line FF′ according to an embodiment of the present disclosure;

FIG. 20 is a top view of a partial structure of a display panel according to an embodiment of the present disclosure according to an embodiment of the present disclosure;

FIG. 21 is a top view of a partial structure of a display panel according to an embodiment of the present disclosure;

FIG. 22 is a top view of a partial structure of a display panel according to an embodiment of the present disclosure;

FIG. 23 is a cross-sectional view of the display panel shown in FIG. 22 along a section line GG′ according to an embodiment of the present disclosure;

FIG. 24 is a cross-sectional view of the display panel shown in FIG. 22 along a section line GG′ according to an embodiment of the present disclosure;

FIG. 25 is a top view of a partial structure of a first mask used in a panel manufacturing process according to an embodiment of the present disclosure;

FIG. 26 is a schematic diagram of a positional relationship between the first mask shown in FIG. 25 and a substrate during manufacturing a thermal insulation structure according to an embodiment of the present disclosure;

FIG. 27 is a top view of a partial structure of a first mask used in a panel manufacturing process according to an embodiment of the present disclosure; and

FIG. 28 is a schematic diagram of a display apparatus according to an embodiment of the present disclosure.

### DESCRIPTION OF EMBODIMENTS

For a better understanding of the technical solutions of the present disclosure, the embodiments of the present disclosure will be described in detail below with reference to the accompanying drawings.

It should be clarified that the described embodiments are merely some embodiments of the present disclosure, rather than all embodiments. Based on the embodiments in the present disclosure, all other embodiments obtained by those of ordinary skill in the arts shall fall within the protection scope of the present disclosure.

The terms used in the embodiments of the present disclosure are for the purpose of describing particular embodiments only and are not intended to limit the present disclosure. As used in the embodiments of the present disclosure and the appended claims, the singular forms “a/an”, “said” and “the” are intended to include the plural forms as well, unless the context clearly indicates otherwise.

It should be understood that the term “and/or” as used herein is merely an association relationship describing associated objects, meaning that three relationships may exist. For example, “A and/or B” may mean: A exists alone, A and B exist together, or B exists alone. In addition, the character “/” herein generally indicates that the associated objects are in an “or” relationship.

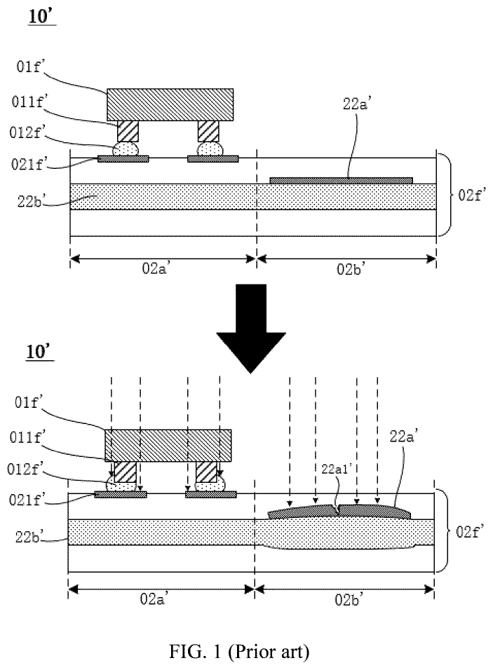

FIG. 1 is a schematic diagram of a partial structure of a display panel in the related art. For ease of understanding, FIG. 1 illustrates a partial structure of the display panel during bonding of light-emitting devices.

In the related art, as shown in FIG. 1, during the manufacturing process of a conventional display panel 10′, after aligning the light-emitting device 01f′ with the substrate 02f′, projections of the connection electrode 011f′ of the light-emitting device 01f′ and the bonding electrode 021f′ of the substrate 02f′ onto the substrate 02f′ both fall within the bonding region 02a′. At this time, the bonding region 02a′ is irradiated by laser, and the eutectic layer structure 012f′ between the connection electrode 011f′ and the bonding electrode 021f′ is heated and becomes molten under laser irradiation. Then, after the eutectic layer structure 012f′ is cooled, the bonding of the light-emitting device 01f′ is achieved. During laser irradiation, besides the bonding region 02a′, the adjacent non-bonding region 02b′ is inevitably irradiated by laser as well.

At this time, the device structure 22a′ located in the non-bonding region 02b′ is also irradiated by laser. It should be noted that the device structure 22a′ may be a structure on a metal layer. Considering that metal structures exhibit strong temperature-increasing characteristic under laser irradiation, the device structure 22a′ generates heat after being irradiated by laser. Furthermore, the non-bonding region 02b′ also includes a partial organic layer structure 22b′, which readily absorbs heat generated by the device structure 22a′. After absorbing heat, the organic layer structure 22b′ tends to expand due to heat (because organic materials in the organic layer structure 22b′ easily produce water vapor and the like upon heating, thereby causing volume expansion). Thermal expansion of the organic layer structure 22b′ tends to increase the risk of damage (e.g., fracture 22a1′) to partial structures (especially partial circuit structures) in the non-bonding region 02b′, thereby increasing the risk of panel failure.

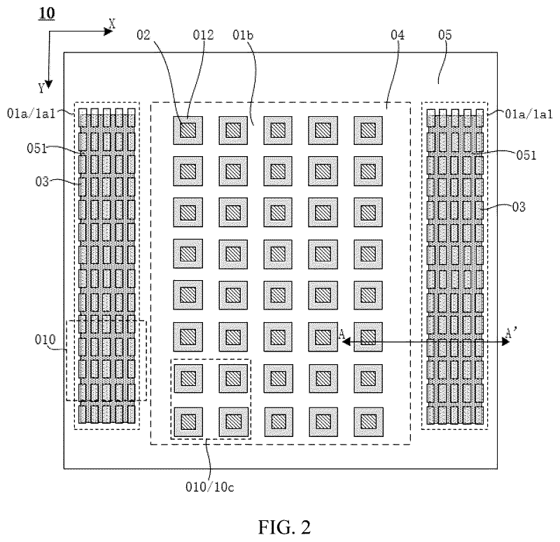

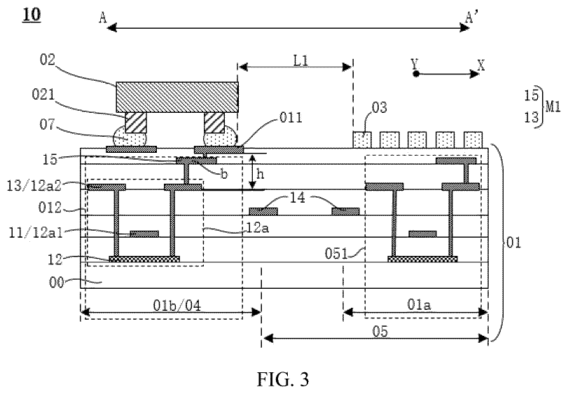

FIG. 2 is a top view of a partial structure of a display panel according to an embodiment of the present disclosure, and FIG. 3 is a cross-sectional view of the display panel shown in FIG. 2 along a section line AA′ according to an embodiment of the present disclosure.

In order to address to the above problems, the present disclosure provides a display panel 10. With reference to FIG. 2 and FIG. 3, the display panel 10 includes an array substrate 01 and may further include light-emitting devices 02. A connection electrode 021 of each light-emitting device 02 may be electrically connected to a pixel electrode 011 of the array substrate 01 via a connection structure 07. During bonding of the light-emitting device 02 onto the array substrate 01, the connection structure 07 may be formed by bonding laser irradiation. Multiple light-emitting devices 02 may be arranged in an array along a first direction X and a second direction Y.

The pixel electrode 011 may receive a driving current provided by a pixel circuit 012 included in the array substrate 01 and transmit the driving current to the light-emitting device 02. The pixel circuit 012 may include a transistor 12a. A gate electrode 12a1 of the transistor 12a may be located in a first metal layer 11, which is disposed on a side of an active layer 12 away from the substrate 00. Source and drain electrodes 12a2 of the transistor 12a may be located in a second metal layer 13, which is disposed on a side of a third metal layer 14 away from the first metal layer 11. The transistor 12a may be electrically connected to the pixel electrode 011 via a cross-layer connection structure b, which may include a portion located in a fourth metal layer 15. The fourth metal layer 15 is disposed on a side of the second metal layer 13 away from the third metal layer 14.

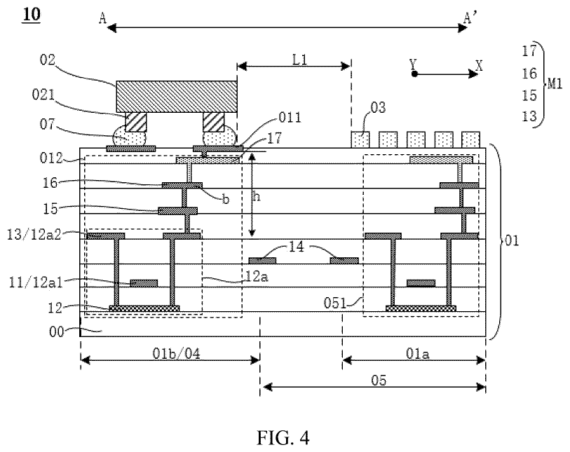

FIG. 4 is a cross-sectional view of the display panel shown in FIG. 2 along a section line AA′ according to an embodiment of the present disclosure.

In addition, in some embodiments, as shown in FIG. 4, the cross-layer connection structure b may further include portions respectively located in a fifth metal layer 16 and a sixth conductive layer 17. The fifth metal layer 16 is disposed between the fourth metal layer 15 and the layer where the pixel electrode 011 is located, and the sixth conductive layer 17 is disposed on a side of the fifth metal layer 16 away from the fourth metal layer 15.

The first metal layer 11, the second metal layer 13, and the third metal layer 14 may include metal materials such as molybdenum. The fourth metal layer 15 and the fifth metal layer 16 may include metal materials such as titanium and aluminum. The sixth conductive layer 17 may include indium tin oxide.

The above layers (the fourth metal layer 15, the fifth metal layer 16, and the sixth conductive layer 17) where the cross-layer connection structure b is located may be regarded as conductive layers relatively adjacent to the layer where the pixel electrode 011 is located.

The array substrate 01 further includes a substrate 00, a first-type conductive layer M1, and thermal insulation structures 03. The thermal insulation structures 03 are disposed on a side of the first-type conductive layer M1 away from the substrate 00. In some embodiments, the layer where the thermal insulation structures 03 are located may be disposed on a side of the layer where the pixel electrode 011 is located away from the substrate 00. During manufacturing of the display panel 10, if the first-type conductive layer M1 is irradiated by bonding laser, the irradiated portion of the first-type conductive layer M1 tends to generate considerable heat. Therefore, to prevent the first-type conductive layer M1 from generating excessive heat under irradiation and thereby causing expansion of organic layers, the thermal insulation structures 03 are provided in the present disclosure. The thermal insulation structures 03 can absorb part of the energy of the bonding laser irradiated thereon. Correspondingly, when the bonding laser energy is absorbed by the thermal insulation structures 03, the light amount and light intensity of the bonding laser are reduced, so that heat generation of surrounding metals (e.g., structures on the first-type metal layer) after being irradiated by the bonding laser is correspondingly reduced. Therefore, instead of easily releasing heat outward after being irradiated by the bonding laser, the thermal insulation structures 03 can mitigate the effect caused by heat generation of surrounding metals (e.g., structures on the first-type metal layer) after laser irradiation.

With reference to FIG. 3 and FIG. 4, the first-type conductive layer M1 includes a first-type metal layer. The first-type metal layer may include the above-mentioned conductive layers relatively adjacent to the layer where the pixel electrode 011 is located, such as the fourth metal layer 15 and the fifth metal layer 16. Besides the above-mentioned conductive layers relatively adjacent to the layer where the pixel electrode 011 is located, the first-type metal layer may also include the second metal layer 13 where the source and drain electrodes 12a2 of the transistor 12a are located. On the other hand, the first-type metal layer may refer to a metal layer structure with a depth h within a range of h≤8 μm, i.e., in a direction perpendicular to the plane where the display panel 10 is located, a metal layer structure between the layer where the pixel electrode 011 is located and the substrate 00, whose distance from the layer where the pixel electrode 011 is located falls within the range of h, may be classified as the first-type metal layer.

As shown in FIG. 2, the display panel 10 further includes a first region 01a and a second region 01b. A metal distribution ratio corresponding to the first region 01a is P1, and a metal distribution ratio corresponding to the second region 01b is P2, where P1>P2. The metal distribution ratio is defined as a ratio of a projection area of a portion of the first-type metal layer corresponding to a unit region on the substrate 00 to an area of the unit region.

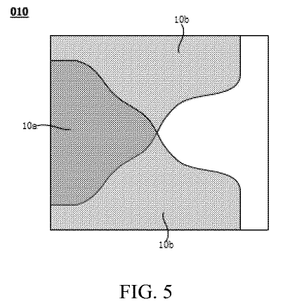

FIG. 5 is a top view of a first-type conductive layer distributed in a selected unit region according to an embodiment of the present disclosure. For ease of understanding, the pattern-filled region in FIG. 5 represents a projection distribution region of the first-type conductive layer in a top view. Since the first-type conductive layer may include multiple conductive layers, an overlapping portion between respective projections of the conductive layers corresponds to an overlapping region (i.e., multiple conductive layers overlap in the overlapping region), and an non-overlapping portion corresponds to a non-overlapping region (i.e., no overlapping between the conductive layers exists in the non-overlapping region). The pattern-filled region may thus be regarded as a combination of the above overlapping region and non-overlapping region.

Both the first region 01a and the second region 01b of the display panel 10 may be provided with metal structures. Specifically, the first-type conductive layer M1 may be distributed in both the first region 01a and the second region 01b. With reference to FIG. 2 and FIG. 5, the metal distribution ratios corresponding to the first region 01a and the second region 01b may be calculated as follows.

First, a unit region 010 is randomly selected within a target region. With reference to FIG. 2 and FIG. 5, a projection area of the unit region 010 is S, where S=N×s1, N is an integer and N≥1, and s1 is a projection area of one sub-region 10c. A single sub-region 10c may include one pixel unit, the pixel unit may include multiple light-emitting devices 02, and light-emitting colors respectively corresponding to multiple light-emitting devices 02 may include blue, green, or red. For example, as shown in FIG. 2, the projection area S of the selected unit region 010 may satisfy: S=s1, and a projection range corresponding to a single sub-region 10c may cover a projection corresponding to a single pixel unit (which may include four light-emitting devices 02).

Next, a projection distribution area F of the first-type metal layer in the unit region 010 is calculated, where F=F1+F2, F1 is a projection area of the overlapping region 10a, and F2 is a projection area of the non-overlapping region 10b. According to the projection area S of the unit region 010 and the projection distribution area F of the first-type metal layer, a metal distribution ratio P is obtained as P=F/S×100%.

The metal distribution ratio P1 in the first region 01a and the metal distribution ratio P2 in the second region 01b may be obtained respectively according to the above calculation method.

The thermal insulation structures 03 are disposed in the first region 01a, and the thermal insulation structures 03 at least partially overlap the first-type metal layer in a direction perpendicular to the plane where the display panel 10 is located.

In the embodiments of the present disclosure, a larger metal distribution ratio P indicates a larger distribution area of the first-type metal layer in this region, and the influence of heat generation upon irradiation of bonding laser onto the first-type metal layer tends to be greater. In the present embodiments, disposing the thermal insulation structures 03 in the first region 01a helps to alleviate abnormal temperature in a region with a relatively large metal distribution ratio P caused by bonding laser irradiation, thereby reducing the risk of failure in the first region 01a due to expansion of organic layers. Furthermore, since the thermal insulation structures 03 are disposed on a side of the first-type metal layer away from the substrate 00, when the thermal insulation structures 03 overlap the first-type metal layer, the thermal insulation structures 03 can shield the first-type metal layer, thereby reducing the amount of laser irradiated onto the first-type metal layer. During the bonding process, bonding laser irradiates the thermal insulation structures 03 first, and energy carried by the bonding laser is preferentially absorbed by the thermal insulation structures 03, thereby weakening the intensity of the remaining laser and further reducing heat generation in the irradiated portion of the first-type metal layer. Therefore, the design of the present embodiments helps reduce heat generated by the first-type conductive layer M1 during bonding, lowers the risk of thermal expansion of nearby organic layers, thereby alleviating or eliminating the risk of damage to the integrity of some device structures, and ensures normal working state of the panel.

In some embodiments, as shown in FIG. 2, the display panel 10 may include a display region 04 and a non-display region 05, and the non-display region 05 may at least partially surround the display region 04. The display region 04 may include pixel circuits 012, at least part of which may be disposed in the first-type conductive layer M1. The non-display region 05 may include gate driving circuits 051 configured to provide scan signals to the pixel circuits 012, and at least part of the gate driving circuits 051 may be disposed in the first-type conductive layer M1. Specifically, the gate driving circuits 051 may also include transistor structures (which may be the same as the transistor 12a described above). Under a narrow-bezel design of the display panel 10, an area for arranging circuit structures in the non-display region 05 is compressed, so that a metal distribution ratio corresponding to the non-display region 05 may be relatively large. In particular, a region where the gate driving circuits 051 are distributed has an even larger metal distribution ratio, and thus the thermal insulation structures 03 may be disposed for this region to specifically improve the influence of bonding laser on temperature variation in this region, thereby prominently reducing the risk of failure in the region. Correspondingly, the first region 01a may correspond to a region where the gate driving circuits 051 are disposed (i.e., located in the non-display region 05), and the second region 01b may be located in the display region 04.

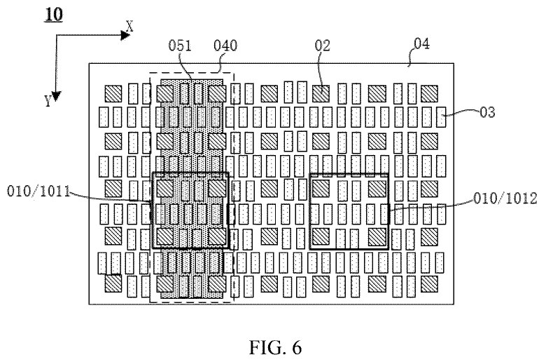

FIG. 6 is a top view of a partial structure of a display panel according to an embodiment of the present disclosure. For ease of understanding, FIG. 6 illustrates the distribution among gate driving circuits, light-emitting devices, and thermal insulation structures in a top view, without showing circuit structures such as pixel circuits.

In some embodiments, as shown in FIG. 6, the display panel 10 may include a display region 04, which may include multiple light-emitting devices 02 arranged in an array along a first direction X and a second direction Y. The display region 04 may include a first sub-display region 040, and the gate driving circuits 051 may be disposed in the first sub-display region 040.

Multiple thermal insulation structures 03 may be disposed in the display region 04, and the thermal insulation structures 03 located in the first sub-display region 040 may overlap the gate driving circuits 051 in a direction perpendicular to the plane where the display panel 10 is located. In this case, the thermal insulation structures 03 located in the first sub-display region 040 may shield and protect the gate driving circuits 051 in the first sub-display region 040.

To compare differences in conductive layer distribution densities corresponding to the first sub-display region 040 and other regions in the display region 04, as shown in FIG. 6, a first unit region 1011 may be selected in the first sub-display region 040, and a second unit region 1012 may be selected in a region of the display region 04 other than the first sub-display region 040. The first unit region 1011 and the second unit region 1012 have the same area (both may be S). Specifically, orthographic projections corresponding to the first unit region 1011 and the second unit region 1012 may each cover orthographic projections corresponding to four light-emitting devices 02.

With reference to FIG. 5 and FIG. 6, the metal distribution ratios P corresponding to the first unit region 1011 and the second unit region 1012 are calculated respectively with reference to the above calculation method of the metal distribution ratio. In addition to the pixel circuits 012 (not shown) corresponding to the light-emitting devices 02, gate driving circuits 051 are additionally disposed in the first sub-display region 040, which means that the distribution density of circuit structures in the first sub-display region 040 is higher. Therefore, the metal distribution ratio corresponding to the first unit region 1011 is larger than that corresponding to the second unit region 1012.

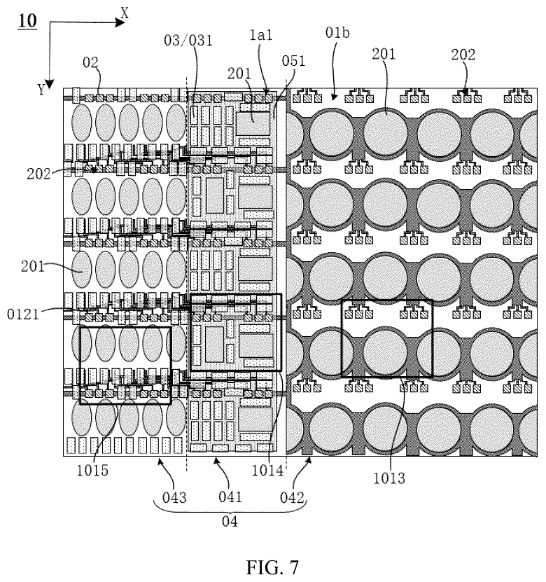

FIG. 7 is a top view of a partial structure of a display panel according to an embodiment of the present disclosure.

In some embodiments, as shown in FIG. 7, the display panel 10 may include a display region 04. The display region 04 may include a compressed display region 041 and a regular display region 042. The compressed display region 041 may be provided with light-emitting devices 02 and gate driving circuits 051, and the regular display region 042 may be provided with light-emitting devices 02. The light-emitting devices 02 may be arranged in an array along a first direction X and a second direction Y. Compared with the regular display region 042, the compressed display region 041 is additionally provided with gate driving circuits 051. In this case, the additionally arranged gate driving circuits 051 in the compressed display region 041 make the circuit structures in the compressed display region 041 more dense. Considering that a partial structure of the gate driving circuits 051 is disposed in the first-type conductive layer M1, thermal insulation structures 03 may be arranged in the compressed display region 041 to avoid an obvious temperature change in the compressed display region 041 during bonding.

In addition, as shown in FIG. 7, multiple regions of the display panel 10 may each include a transparent region 201, and the first-type conductive layer M1 may not be distributed in the transparent region 201. This design helps the display panel 10 achieve relatively high overall light transmittance.

In some embodiments, P1−P2≥20%.

In the embodiments of the present disclosure, when P1−P2≥20% is satisfied, the distribution area difference between the first-type conductive layer M1 in the first region 01a and that in the second region 01b is relatively large. If bonding laser irradiates the first-type conductive layer M1 in both regions, the projection area corresponding to the portion of the first-type conductive layer M1 in the first region 01a that is easily irradiated by the bonding laser may be larger than that in the second region 01b, so that the risk of the temperature-increasing in the first region 01a is higher. Therefore, the arrangement of the thermal insulation structures 03 in the first region 01a can specifically reduce the risk of temperature-increasing in the first region 01a, so as to compensate for the temperature difference between the first region 01a and the second region 01b caused by the above metal distribution ratio difference, thereby reducing the temperature difference between the two regions and further improve the working state of the panel.

In some embodiments, with reference to FIG. 2 and FIG. 7, the first region 01a includes a first sub-region 1a1, and the first sub-region 1a1 is located on a side of the second region 01b adjacent to an edge of the display panel 10.

As shown in FIG. 2, the first sub-region 1a1 may be located in the non-display region 05, and in this case, the second region 01b may be located in the display region 04.

As shown in FIG. 7, the first sub-region 1a1 may be located in the compressed display region 041, and in this case, the second region 01b may be located in the regular display region 042.

The display panel 10 further includes gate driving circuits 051. The gate driving circuits 051 are located in the first sub-region 1a1, and at least partial structure of the gate driving circuits 051 is located in the first-type conductive layer M1. The metal distribution ratio in the first sub-region 1a1 where the gate driving circuits 051 are located may be relatively high, that is, the first sub-region 1a1 has a high risk of heat generation during bonding, and the thermal insulation structures 03 may be arranged in this region for adjustment.

The thermal insulation structures 03 include first-type thermal insulation structures 031. An orthographic projection of the first-type thermal insulation structures 031 on the substrate 00 at least partially overlaps an orthographic projection of the gate driving circuits 051 on the substrate 00. In this case, the first-type thermal insulation structures 031 can shield the gate driving circuits 051, helping to reduce the amount of bonding laser irradiated onto the gate driving circuits 051, lower the heat generation of the portion of the first-type conductive layer M1 corresponding to the gate driving circuits 051, and reduce the risk of organic layer expansion in this region.

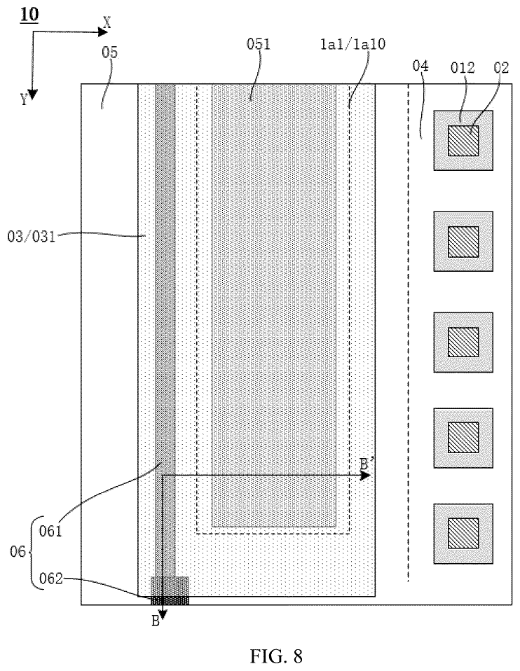

FIG. 8 is a top view of a partial structure of a display panel according to an embodiment of the present disclosure.

In some embodiments, as shown in FIG. 8, the first sub-region 1a1 includes a first circuit region 1a10, and the gate driving circuits 051 are all located in the first circuit region 1a10. In this case, the first circuit region 1a10 may be located in the non-display region 05. An orthographic projection of the gate driving circuits 051 on the substrate 00 may extend along a second direction Y, and the second direction Y may intersect the first direction X. The first circuit region 1a10 is located within an orthographic projection of the first-type thermal insulation structures 031 on the substrate 00, that is, the first-type thermal insulation structures 031 may cover the first circuit region 1a10 in a direction perpendicular to the plane where the display panel 10 is located. With this design, the first-type thermal insulation structures 031 can well shield the gate driving circuits 051, and the amount of bonding laser irradiated onto the gate driving circuits 051 during bonding can be reduced, which is conducive to lowering the heat generation of the first-type conductive layer M1 in the first circuit region 1a10. It should be noted that the first-type thermal insulation structures 031 under this design may correspond to a relatively large area, and the problem of electrostatic accumulation on the first-type thermal insulation structures 031 needs to be considered in the actual manufacturing process.

The display panel 10 further includes an electrostatic discharge structure 06. The electrostatic discharge structure 06 can discharge the electrostatic charge accumulated in the display panel 10, so as to reduce the influence of electrostatic charge accumulation on the working state of the display panel 10. The first-type thermal insulation structures 031 are electrically connected to the electrostatic discharge structure 06, so that the electrostatic charge accumulated in the first-type thermal insulation structures 031 can be discharged through the electrostatic discharge structure 06. With this design, the first-type thermal insulation structures 031 can completely cover the first circuit region 1a10, and the problem of the electrostatic charge accumulation caused by the relatively large arrangement area of the first-type thermal insulation structures 031 can be avoided.

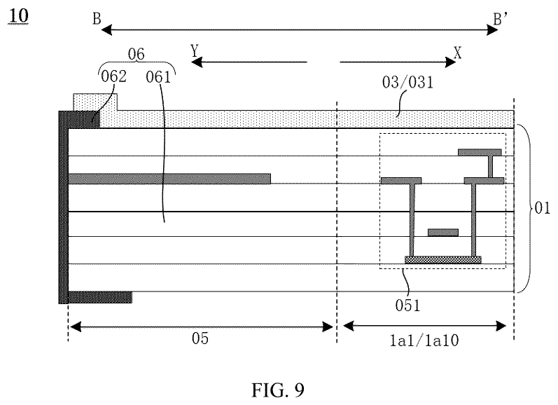

FIG. 9 is a cross-sectional view of the display panel shown in FIG. 8 along a section line BB′ according to an embodiment of the present disclosure.

In some embodiments, with reference to FIG. 8 and FIG. 9, the electrostatic discharge structure 06 includes a first portion 061 and a pin 062. At least part of the first portion 061 is located between the layer where the thermal insulation structures 03 are disposed and the substrate 00. At least part of the pin 062 and the first-type thermal insulation structures 031 are both located on a side of the first-type conductive layer M1 away from the substrate 00.

The first-type thermal insulation structures 031 are electrically connected to the first portion 061 via the pin 062. During the manufacturing process, the part of the thermal insulation structures 03 (i.e., the part of the first-type thermal insulation structures 031) may be directly deposited on a side of the pin 062 away from the substrate 00, so as to achieve electrical connection between the electrostatic discharge structure 06 and the first-type thermal insulation structures 031.

In the embodiments of the present disclosure, the design in which the first-type thermal insulation structures 031 are electrically connected to the first portion 061 via the pin 062 helps simplify the manufacturing steps while realizing electrostatic discharge of the first-type thermal insulation structures 031.

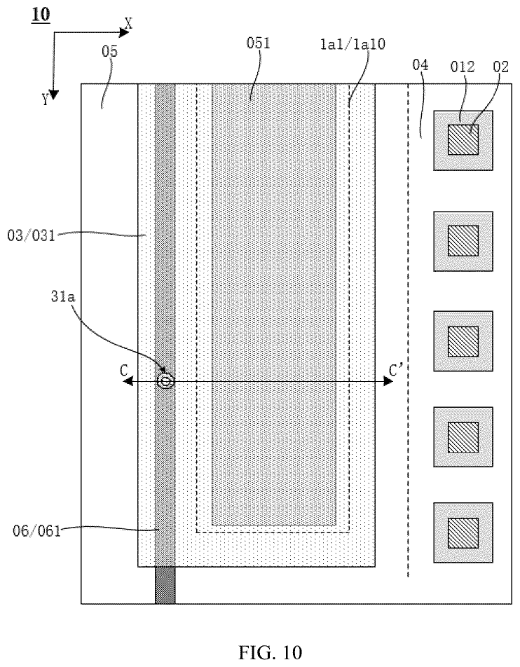

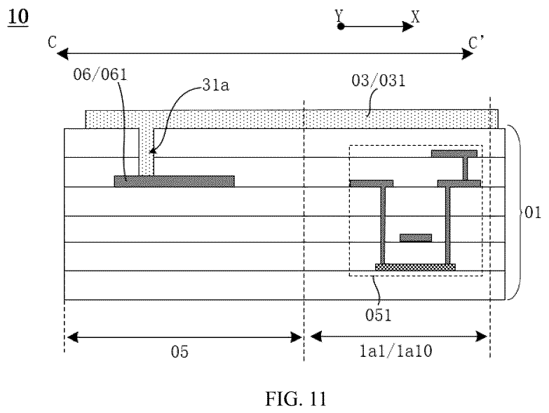

FIG. 10 is a top view of a partial structure of a display panel according to an embodiment of the present disclosure, and FIG. 11 is a cross-sectional view of the display panel shown in FIG. 10 along a section line CC′ according to an embodiment of the present disclosure.

In some embodiments, with reference to FIG. 10 and FIG. 11, the electrostatic discharge structure 06 includes a first portion 061. At least part of the first portion 061 is located between the layer where the thermal insulation structures 03 are disposed and the substrate 00. An orthographic projection of the first portion 061 on the substrate 00 may extend along a second direction Y, and the second direction Y may intersect the first direction X.

The first-type thermal insulation structures 031 are electrically connected to the first portion 061 through a via hole 31a.

In the present embodiments, the first portion 061 can discharge part of the electrostatic charge in the display panel 10. Considering that the first portion 061 and the first-type thermal insulation structures 031 are disposed in different layers, the via hole 31a may be provided to achieve electrical connection between the first-type thermal insulation structures 031 and the first portion 061.

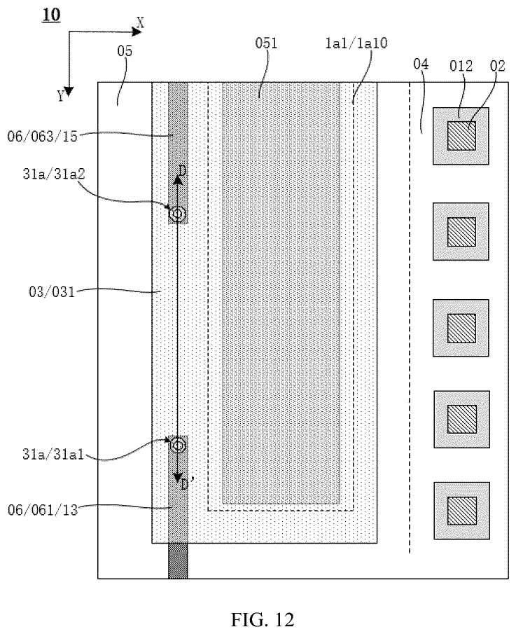

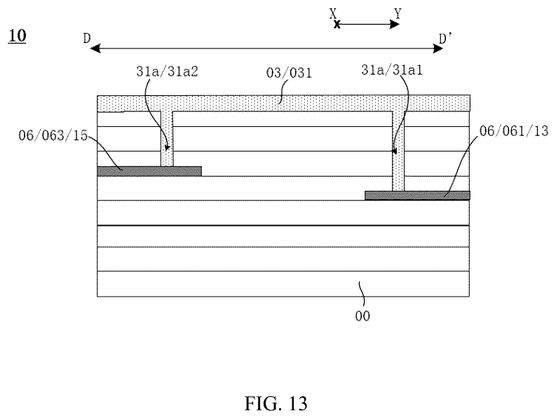

FIG. 12 is a top view of a partial structure of a display panel according to an embodiment of the present disclosure, and FIG. 13 is a cross-sectional view of the display panel shown in FIG. 12 along a section line DD′ according to an embodiment of the present disclosure.

In some embodiments, with reference to FIG. 12 and FIG. 13, the electrostatic discharge structure 06 further includes a second portion 063. The layer where the second portion 063 is disposed is located between the layer where the thermal insulation structures 03 are disposed and the substrate 00, and the first portion 061 and the second portion 063 are disposed in different layers. Specifically, the first portion 061 may be located in the second metal layer 13, and the second portion 063 may be located in the fourth metal layer 15. Considering that the electrostatic discharge structure 06 may form a complete connection loop, the first portion 061 and the second portion 063 located in different layers need to be connected across layers through via structures. Orthographic projections of the first portion 061 and the second portion 063 on the substrate 00 may extend along the second direction Y, and the second direction Y may intersect the first direction X.

The first-type thermal insulation structures 031 are electrically connected to the first portion 061 through a first via hole 31a1, and the first-type thermal insulation structures 031 are electrically connected to the second portion 063 through a second via hole 31a2.

In the embodiments of the present disclosure, the first-type thermal insulation structures 031 may serve as a bridge connection structure for realizing electrical connection between the first portion 061 and the second portion 063. With this design, the first-type thermal insulation structures 031 can not only be used to weaken the influence of bonding laser on the first-type conductive layer M1, but also serve as a part of the electrostatic discharge structure 06.

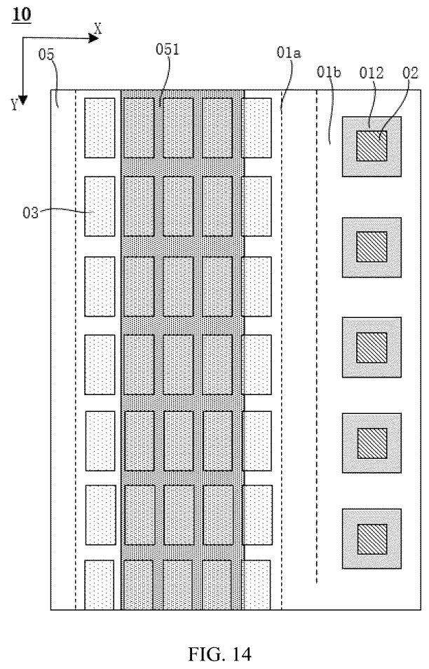

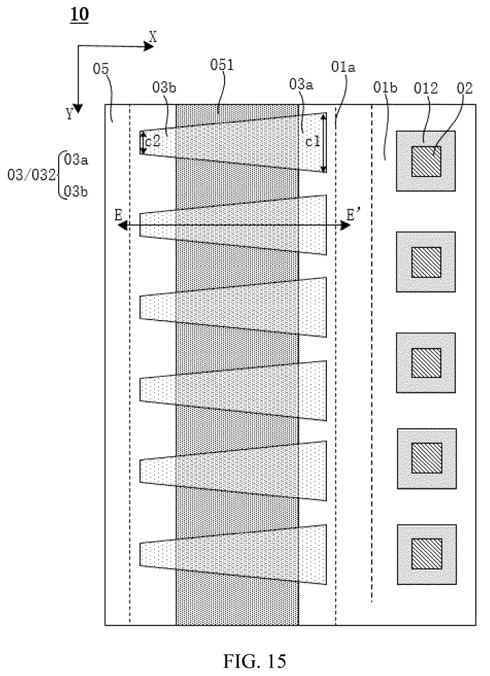

FIG. 14 is a top view of a partial structure of a display panel according to an embodiment of the present disclosure, and FIG. 15 is a top view of a partial structure of a display panel according to an embodiment of the present disclosure.

In some embodiments, as shown in FIG. 14, an aspect ratio m of an orthographic projection of a thermal insulation structure 03 on the substrate 00 is less than or equal to 2, and orthographic projections corresponding to the thermal insulation structures 03 are arranged in a multi-row, multi-column array. In some embodiments, the thermal insulation structures 03 may be arranged in an array along the first direction X and the second direction Y. When the gate driving circuits 051 are located in the non-display region 05 and the first region 01a overlaps the gate driving circuits 051, thermal insulation structures 03 arranged in an array help shield the region where the gate driving circuits 051 are located as much as possible, which is conducive to improving the influence of bonding laser on the temperature in this region.

Alternatively, as shown in FIG. 15, an aspect ratio m of an orthographic projection of a thermal insulation structure 03 on the substrate 00 is greater than 2, at least part of the thermal insulation structures 03 is located in the first sub-region 1a1, and an orthographic projection of the thermal insulation structure 03 extend along the first direction X. The first region 01a includes the first sub-region 1a1, the first sub-region 1a1 is located on a side of the second region 01b adjacent to an edge of the display panel 10, the first direction X is a direction from the first sub-region 1a1 toward the second region 01b, and the first direction X may intersect the second direction Y.

In this design, compared with the non-display region 05, positions irradiated by the bonding laser during bonding are mostly concentrated in the display region 04, so that the temperature-increasing of the part of the first-type conductive layer M1 in the second region 01b due to irradiation is relatively significant. It should be noted that, besides the second region 01b, the part of the non-display region 05 adjacent to the display region 04 is also easily irradiated by the bonding laser. Therefore, a targeted morphological design may be performed for the thermal insulation structure 03 distributed in the part of the non-display region 05 adjacent to the display region 04 (hereinafter referred to as a boundary region). On this basis, in the present embodiments, the orthographic projection corresponding to the thermal insulation structure 03 in the first sub-region 1a1 is designed to extend along the first direction X. This design facilitates the targeted morphological adjustment of the part of the thermal insulation structure 03 located in the above boundary region, so as to meet the requirement of improving the influence of laser irradiation in the boundary region.

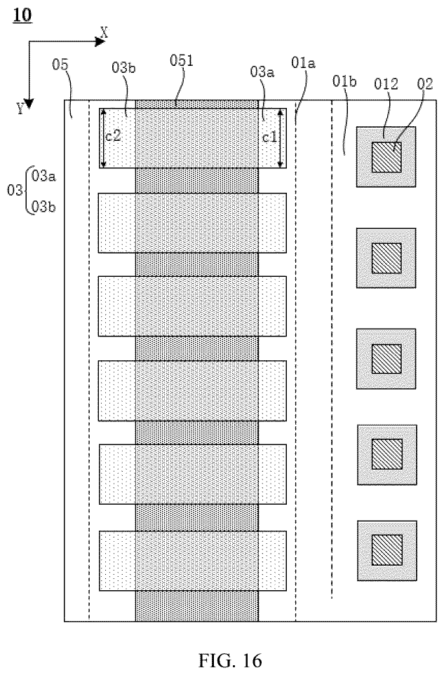

FIG. 16 is a top view of a partial structure of a display panel according to an embodiment of the present disclosure.

In some embodiments, as shown in FIG. 16, an aspect ratio m of an orthographic projection of a thermal insulation structure 03 on the substrate 00 is greater than 2, at least part of the thermal insulation structure 03 is located in the first sub-region 1a1, and an orthographic projection of such thermal insulation structure 03 extends along the first direction X, and the first direction X may intersect the second direction Y. The thermal insulation structure 03 includes a first thermal insulation portion 03a and a second thermal insulation portion 03b. The first thermal insulation portion 03a is located on a side of the second thermal insulation portion 03b adjacent to the second region 01b. A width c1 of an orthographic projection of the first thermal insulation portion 03a on the substrate 00 is equal to a width c2 of an orthographic projection of the second thermal insulation portion 03b on the substrate 00. In the present embodiments, the width of the thermal insulation structure 03 along the first direction X may be regarded as constant, which helps reduce the difficulty of arranging the thermal insulation structure 03.

In some embodiments, as shown in FIG. 15, thermal insulation structures 03 include second-type thermal insulation structures 032. An aspect ratio m of an orthographic projection of a second-type thermal insulation structure 032 on the substrate 00 is greater than 2. The second-type thermal insulation structure 032 is located in the first sub-region 1a1, and an orthographic projection corresponding to the second-type thermal insulation structure 032 extends along the first direction X.

The array substrate 01 further includes pixel electrodes 011. The layer where the pixel electrodes 011 are disposed is located on a side of the first-type conductive layer M1 away from the substrate 00, and the pixel electrodes 011 are electrically connected to the light-emitting devices 02. In a direction perpendicular to the plane where the display panel 10 is located, the pixel electrodes 011 overlap the second region 01b and do not overlap the first sub-region 1a1. During bonding, the bonding laser may irradiate the second region 01b where the pixel electrodes 011 are located and surrounding regions adjacent to the second region 01b. In particular, the above boundary region adjacent to the display region 04 has a higher risk of temperature-increasing of the first-type conductive layer M1 caused by bonding laser irradiation. Therefore, a targeted design may be performed for the morphology of the thermal insulation structure 03 in the boundary region.

A width of an orthographic projection of the second-type thermal insulation structure 032 on the substrate 00 gradually increases along the first direction X. Among the first thermal insulation portion 03a and the second thermal insulation portion 03b included in the second-type thermal insulation structure 032, the first thermal insulation portion 03a is located on a side of the second thermal insulation portion 03b adjacent to the second region 01b, and a width c1 of an orthographic projection of the first thermal insulation portion 03a on the substrate 00 is greater than a width c2 of an orthographic projection of the second thermal insulation portion 03b on the substrate 00.

In the present embodiments, the width of the orthographic projection of the second-type thermal insulation structure 032 varies along the first direction X, and the part of the second-type thermal insulation structure 032 located in the above boundary region has a relatively large orthographic projection width. This means that, within per unit length along the first direction X, the material content of the second-type thermal insulation structure 032 disposed in the boundary region is higher, which is conducive to enhancing the bonding laser shielding effect of the second-type thermal insulation structure 032 in the boundary region, thereby realizing the above targeted design.

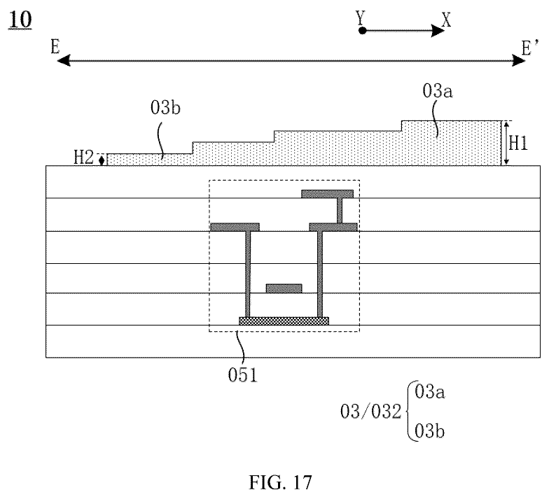

FIG. 17 is a cross-sectional view of the display panel shown in FIG. 15 along a section line EE′ according to an embodiment of the present disclosure.

In some embodiments, with reference to FIG. 15 and FIG. 17, the second-type thermal insulation structure 032 includes a first thermal insulation portion 03a and a second thermal insulation portion 03b. Along the first direction X, the first thermal insulation portion 03a is located on a side of the second thermal insulation portion 03b adjacent to the second region 01b. Compared with the second thermal insulation portion 03b, the first thermal insulation portion 03a is closer to the second region 01b, so that the first thermal insulation portion 03a is more easily irradiated by the bonding laser during the bonding process.

A thickness H1 of the first thermal insulation portion 03a is greater than a thickness H2 of the second thermal insulation portion 03b.

In the embodiments of the present disclosure, a greater thickness of the thermal insulation structure 03 indicates a larger amount of material corresponding to the thermal insulation structure 03 under a fixed projection area, and thus a stronger ability to resist bonding laser irradiation. In the present embodiments, designing H1 >H2 helps to specifically enhance the resistance effect of the first thermal insulation portion 03a against bonding laser irradiation and improve its shielding effect on the first-type conductive layer M1 in the boundary region. In addition, the design that the thickness H2 of the second thermal insulation portion 03b is relatively small also helps to appropriately reduce the material consumption of the thermal insulation structure 03 and save costs on the premise of realizing shielding of the first-type conductive layer M1.

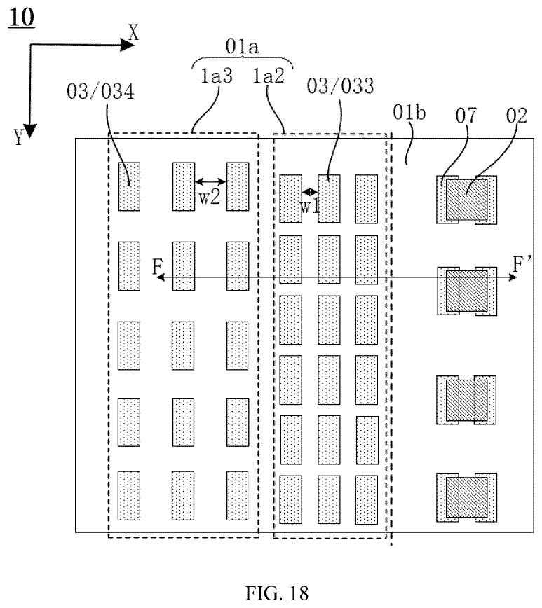

FIG. 18 is a top view of a partial structure of a display panel according to an embodiment of the present disclosure. For ease of understanding, FIG. 18 only shows the distribution of light-emitting devices, connection structures, various thermal insulation structures and the like in a top view.

In some embodiments, as shown in FIG. 18, the first region 01a includes a second sub-region 1a2 and a third sub-region 1a3, and the second sub-region 1a2 is located between the third sub-region 1a3 and the second region 01b. The second sub-region 1a2 and the third sub-region 1a3 may be adjacent along the first direction X, and the first direction X may intersect the second direction Y.

The thermal insulation structures 03 include third-type thermal insulation structures 033 and fourth-type thermal insulation structures 034. The third-type thermal insulation structures 033 are located in the second sub-region 1a2, and the fourth-type thermal insulation structures 034 are located in the third sub-region 1a3. Compared with the third sub-region 1a3, the second sub-region 1a2 is closer to the second region 01b. During the bonding process, considering that the pixel electrodes 011 are disposed in the second region 01b, the first-type conductive layer M1 in the second sub-region 1a2 is at a relatively high risk of being affected by the bonding laser. Therefore, the design of the thermal insulation structures 03 in the second sub-region 1a2 may be adjusted in a targeted manner to compensate for the influence caused by bonding laser irradiation.

In the second sub-region 1a2, a spacing between some adjacent third-type thermal insulation structures 033 is w1, and in the third sub-region 1a3, a spacing between some adjacent fourth-type thermal insulation structures 034 is w2, where w1<w2.

In the embodiments of the present disclosure, in a unit region with a fixed area, a denser distribution of the thermal insulation structures 03 indicates a better shielding effect provided by the thermal insulation structures 03 in the unit region, and a weaker temperature change caused by irradiation of the bonding laser on the first-type conductive layer M1 in the unit region. Therefore, the design of w1<w2 in the present embodiments means that the thermal insulation structures 03 (third-type thermal insulation structures 033) are arranged more densely in the second sub-region 1a2, thereby helping to specifically enhance the stability of temperature variation in the second sub-region 1a2 under bonding laser irradiation, and further ensuring the normal working state of the panel.

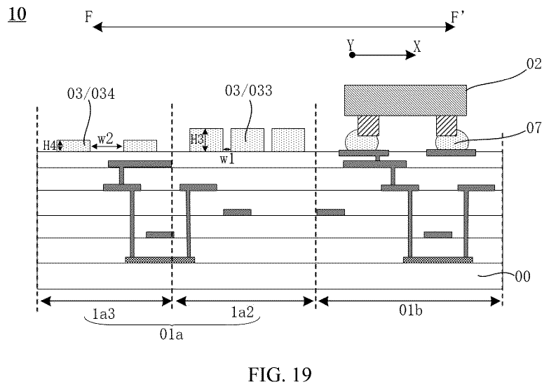

FIG. 19 is a cross-sectional view of the display panel shown in FIG. 18 along a section line FF′ according to an embodiment of the present disclosure.

In some embodiments, with reference to FIG. 18 and FIG. 19, a thickness H3 of a third-type thermal insulation structure 033 is greater than a thickness H4 of a fourth-type thermal insulation structure 034.

In the embodiments of the present disclosure, a greater thickness of the thermal insulation structure 03 indicates a larger amount of material corresponding to the thermal insulation structure 03, and thus a stronger ability to resist bonding laser irradiation. In the present embodiments, designing H3>H4 helps to specifically enhance the resistance effect of the third-type thermal insulation structures 033 against bonding laser irradiation and improve their shielding effect on the first-type conductive layer M1 in the second sub-region 1a2. In addition, the design that the thickness H4 of the fourth-type thermal insulation structure 034 is relatively small also helps to appropriately reduce the material consumption of the thermal insulation structures 03 and save costs on the premise of realizing shielding of the first-type conductive layer M1.

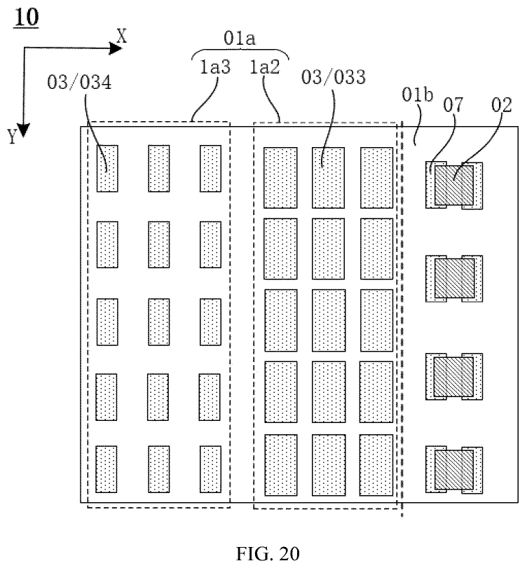

FIG. 20 is a top view of a partial structure of a display panel according to an embodiment of the present disclosure.

In some embodiments, as shown in FIG. 20, an orthographic projection area of a third-type thermal insulation structure 033 on the substrate 00 is greater than an orthographic projection area of a fourth-type thermal insulation structure 034 on the substrate 00. The region where the third-type thermal insulation structures 033 are located and the region where the fourth-type thermal insulation structures 034 are located may be adjacent along the first direction X, and the first direction X may intersect the second direction Y.

In the embodiments of the present disclosure, a larger orthographic projection area of the thermal insulation structure 03 indicates a larger effective shielding range of the thermal insulation structure 03 and a better shielding effect on the first-type conductive layer M1. In the present embodiments, designing a larger orthographic projection area of the third-type thermal insulation structure 033 is intended to maximize the shielding effect of the third-type thermal insulation structure 033 on the portion of the first-type conductive layer M1 located in the second sub-region 1a2, so as to specifically reduce the risk that the first-type conductive layer M1 in the second sub-region 1a2 is irradiated by the bonding laser.

In some embodiments, the metal distribution ratio corresponding to the second sub-region 1a2 is greater than the metal distribution ratio corresponding to the third sub-region 1a3.

The targeted designs of the spacing, thickness, projection area and the like of the thermal insulation structures 03 in the above-mentioned embodiments can mainly reduce the influence of bonding laser irradiation on temperature variation in the second sub-region 1a2, so that the risk of abnormal temperature-increasing in the second sub-region 1a2 is low. At this time, on the premise of not affecting the working state of the display panel 10, a relatively large number of circuit structures may be disposed in the second sub-region 1a2 (which means that the metal distribution ratio in the second sub-region 1a2 is also relatively large), so as to adapt to the limited space in the non-display region 05 and help meet the requirement of narrow-bezel design.

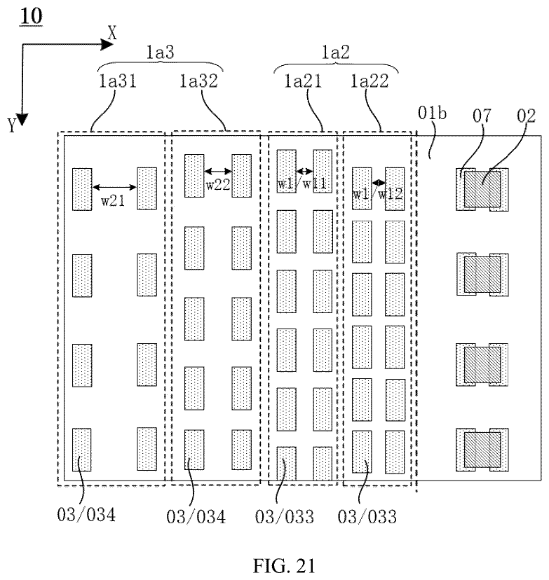

FIG. 21 is a top view of a partial structure of a display panel according to an embodiment of the present disclosure.

In some embodiments, the second sub-region 1a2 is adjacent to the third sub-region 1a3, and the metal distribution ratio P12 corresponding to the second sub-region 1a2 and the metal distribution ratio P13 corresponding to the third sub-region 1a3 satisfy: P12−P13≥10%. Considering a certain difference between the metal distribution ratios corresponding to the second sub-region 1a2 and the third sub-region 1a3, when both sub-regions are irradiated by the bonding laser, the temperature-increasing in the second sub-region 1a2 tends to be more significant than that in the third sub-region 1a3, resulting in an obvious temperature difference between the two sub-regions. To avoid inconsistent device states in the two sub-regions caused by an obvious temperature difference, the arrangement of the thermal insulation structures 03 corresponding to the two sub-regions may be adaptively adjusted. For example, the thermal insulation structures 03 may be arranged more densely in the second sub-region 1a2 than in the third sub-region 1a3.

As shown in FIG. 21, the third sub-region 1a3 includes a first zone 1a31 and a second zone 1a32, and the second zone 1a32 is located on a side of the first zone 1a31 adjacent to the second sub-region 1a2. Considering that the metal distribution ratio in the second sub-region 1a2 is relatively large and the second zone 1a32 is closer to the second sub-region 1a2, when the temperature rises in the second sub-region 1a2, the corresponding heat is more easily transferred to the second zone 1a32 closer to the second sub-region 1a2.

In the first zone 1a31, a spacing between some adjacent fourth-type thermal insulation structures 034 is w21. In the second zone 1a32, a spacing between some adjacent fourth-type thermal insulation structures 034 is w22, where w1<w22<w21. The above spacing may be along the first direction X or the second direction Y.

In the embodiments of the present disclosure, the design of w22<w21 can specifically improve the stability of temperature variation in the second zone 1a32. Even if heat is transferred from the second sub-region 1a2 to the second zone 1a32, such heat can be absorbed by the densely arranged fourth-type thermal insulation structures 034 in the second zone 1a32. In addition, w1<w22<w21 can form a gradient density distribution design of the thermal insulation structures 03 in different regions, so as to adapt to temperature variation ranges caused by differences in metal distribution ratio, relative position and the like in different regions, thereby further ensuring the working state of the display panel 10.

In some embodiments, as shown in FIG. 21, the second sub-region 1a2 includes a third zone 1a21 and a fourth zone 1a22, and the third zone 1a21 is located on a side of the fourth zone 1a22 adjacent to the third sub-region 1a3. Considering that the second sub-region 1a2 is located on a side of the third sub-region 1a3 adjacent to the second region 01b, the fourth zone 1a22 is closer to the second region 01b than the third zone 1a21. Therefore, during bonding of the light-emitting devices 02 in the second region 01b, the portion of the first-type conductive layer M1 in the fourth zone 1a22 is at a higher risk of being irradiated by the bonding laser than that in the third zone 1a21. Therefore, the arrangement of the thermal insulation structures 03 in the fourth zone 1a22 may be adjusted in a targeted manner to enhance the stability of temperature variation in the fourth zone 1a22.

In the third zone 1a21, a spacing between some adjacent third-type thermal insulation structures 033 is w11. In the fourth zone 1a22, a spacing between some adjacent third-type thermal insulation structures 033 is w12, where w12<w11<w22. The above spacing may be along the

### First Direction X or the Second Direction Y.

In the embodiments of the present disclosure, w12<w11 means that the third-type thermal insulation structures 033 are arranged more densely in the fourth zone 1a22 than in the third zone 1a21, so that the stability of temperature variation in the fourth zone 1a22 can be higher than that in the third zone 1a21. In addition, considering that the second sub-region 1a2 is closer to the second region 01b than the third sub-region 1a3, w12<w11<w22 may be set to realize that the arrangement density of the thermal insulation structures 03 in both zones of the second sub-region 1a2 is higher than that in the third sub-region 1a3.

In some embodiments, as shown in FIG. 3, the array substrate 01 further includes pixel electrodes 011. The layer where the pixel electrodes 011 are disposed is located on a side of the first-type conductive layer M1 away from the substrate 00, and the pixel electrodes 011 are electrically connected to the light-emitting devices 02 via a connection structure 07. The material of the connection structure 07 may be an eutectic material. Before bonding, the above eutectic material may be disposed between the connection electrode 021 of the light-emitting device 02 and the pixel electrode 011. During bonding, the connection structure 07 is deformed under irradiation of the bonding laser, and finally forms the connection structure 07.

During the bonding process, the thermal insulation structure 03 undergoes a morphological change under irradiation of the bonding laser. Specifically, when the thermal insulation structure 03 is irradiated by the bonding laser, part of the energy in the bonding laser is transferred to the thermal insulation structure 03, and the temperature of the thermal insulation structure 03 rises after obtaining the energy. When its temperature rises to the melting point, the thermal insulation structure 03 may undergo a morphological change (from a solid state to a liquid state). However, such morphological change may be accompanied by absorption of surrounding heat. During the morphological change, heat generated by irradiation of the bonding laser on the thermal insulation structure 03, and even heat generated by irradiation on partial structures near the thermal insulation structure 03 (such as the first-type conductive layer M1), can be absorbed by the thermal insulation structure 03. Therefore, the arrangement of the thermal insulation structure 03 can reduce the temperature rise caused by bonding laser irradiation, thereby alleviating expansion caused by the temperature rise.

A gap L1 is provided between the thermal insulation structure 03 and the connection structure 07. In this case, the thermal insulation structure 03 and the connection structure 07 are regarded as electrically insulated. Specifically, L1≥3 μm.

In the embodiments of the present disclosure, considering that the bonding laser is usually irradiated near the region where the pixel electrodes 011 are disposed, i.e., the risk of abnormal temperature change near the pixel electrodes 011 due to bonding laser irradiation is relatively high, in the present embodiments, the thermal insulation structures 03 may be disposed in a region adjacent to the connection structure 07 to improve the stability of temperature variation in the above region. However, this design reduces the spacing between the connection structure 07 and the thermal insulation structure 03. To avoid a short circuit therebetween, the present embodiments adopt a design in which a gap L1 is provided between the connection structure 07 and the thermal insulation structure 03, so as to prevent the display state from being affected by a short circuit between the connection structure 07 and the thermal insulation structure 03.

In some embodiments, the array substrate 01 further includes pixel electrodes 011. The layer where the pixel electrodes 011 are disposed is located on a side of the first-type conductive layer M1 away from the substrate 00, and the pixel electrodes 011 are electrically connected to the light-emitting devices 02 via a connection structure 07.

Both the material of the thermal insulation structure 03 and the material of the connection structure 07 include metallic tin.

In the present embodiments, metallic tin is added to the connection structure 07 to realize the bonding process by utilizing its low melting point. When metallic tin is added to the material of the thermal insulation structure 03, under irradiation of the bonding laser, the temperature of the thermal insulation structure 03 can more easily reach the melting point to undergo the above morphological change, i.e., the thermal insulation structure 03 can exert a heat absorption effect on the surrounding heat at an early stage of the temperature-increasing caused by bonding laser irradiation. This design helps control the temperature of the panel at a low level by using the thermal insulation structure 03, further reducing the risk of damage to structures in the panel caused by expansion.

In some embodiments, as shown in FIG. 3, the thermal insulation structures 03 and the connection structure 07 are disposed in the same layer. In the present embodiments, when the thermal insulation structures 03 and the connection structure 07 include the same material (such as metallic tin, chemical symbol Sn) and are also disposed in the same layer, the thermal insulation structures 03 and the connection structure 07 can be fabricated in the same fabrication process, helping reduce fabrication difficulty and save costs.

In some embodiments, the thermal insulation structure 03 may include metallic indium (chemical symbol In). Considering that metallic indium has characteristics such as high ductility and low melting point, under irradiation of the bonding laser, the thermal insulation structure 03 containing metallic indium can achieve a favorable heat absorption effect and help reduce the fabrication difficulty of the thermal insulation structure 03.

In some embodiments, the thermal insulation structure 03 may include metallic gold (chemical symbol Au) and metallic silver (chemical symbol Ag). In the present embodiments, metallic gold and silver have high light reflectivity. When the above two materials are used as materials of the thermal insulation structure 03, they help enhance the reflection effect of the thermal insulation structure 03 on the bonding laser, thereby reducing the amount of bonding laser irradiated toward the first-type conductive layer M1 therebelow.

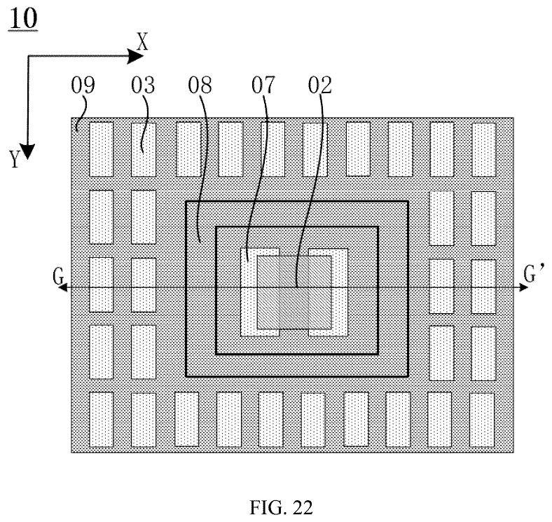

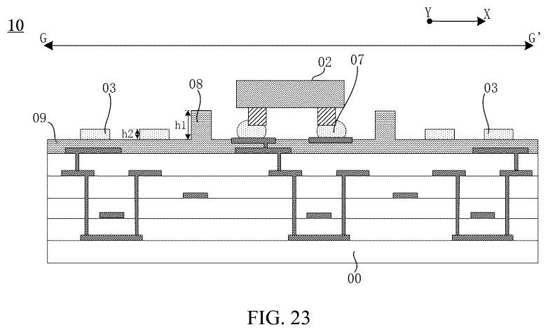

FIG. 22 is a top view of a partial structure of a display panel according to an embodiment of the present disclosure, and FIG. 23 is a cross-sectional view of the display panel shown in FIG. 22 along a section line GG′ according to an embodiment of the present disclosure.

In some embodiments, with reference to FIG. 22 and FIG. 23, the display panel 10 further includes a protruding structure 08, and the protruding structure 08 includes an electrical insulating material. Specifically, the display panel 10 may further include an insulating layer 09, and the insulating layer 09 may be disposed between the first-type conductive layer M1 and the layer where the connection structure 07 is disposed. The protruding structure 08 may be regarded as a part of the insulating layer 09 on a side away from the substrate 00.

In a direction parallel to the plane where the display panel 10 is located, the protruding structure 08 is disposed between the thermal insulation structure 03 and the connection structure 07. It should be noted that, under irradiation of the bonding laser, the materials of the thermal insulation structure 03 and the connection structure 07 may both undergo the above morphological change and be in a liquid state (with high fluidity) at a certain time, thereby easily causing a risk of a short circuit between the thermal insulation structure 03 and the connection structure 07. Under the design of the present embodiments, the protruding structure 08 can be regarded as a three-dimensional barrier structure between the thermal insulation structure 03 and the connection structure 07, helping avoid a short circuit therebetween, thereby ensuring normal display of the light-emitting devices 02 on the premise of improving the stability of temperature variation.

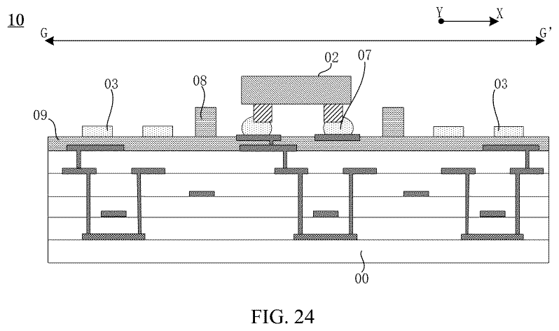

FIG. 24 is a cross-sectional view of the display panel shown in FIG. 22 along a section line GG′ according to an embodiment of the present disclosure.

In some embodiments, as shown in FIG. 24, the protruding structure 08 is disposed on a side of the insulating layer 09 away from the substrate 00. In this case, the protruding structure 08 may be regarded as an additional insulating structure disposed on the side of the insulating layer 09 away from the substrate 00.

In some embodiments, as shown in FIG. 22, an orthographic projection of the protruding structure 08 on the substrate 00 at least partially surrounds an orthographic projection of the connection structure 07 on the substrate 00.

In the present embodiments, the design in which the protruding structure 08 surrounds the connection structure 07 enables the protruding structure 08 to serve as a wall-like structure, which can isolate and protect the connection structure 07, further reducing the risk of a short circuit between the connection structure 07 and the thermal insulation structure 03.

In some embodiments, as shown in FIG. 23, in a direction perpendicular to the plane where the display panel 10 is located, a height h1 of the protruding structure 08 is greater than a thickness h2 of the thermal insulation structure 03.

In the embodiments of the present disclosure, the design of h1>h2 means that the protruding structure 08 can be regarded as a wall-like structure higher than the thermal insulation structure 03. With this design, even if the material of the thermal insulation structure 03 flows in a molten state during the bonding process, the protruding structure 08 can block further diffusion of the material toward the position of the connection structure 07, effectively avoiding a short circuit between the connection structure 07 and the thermal insulation structure 03.

In some embodiments, as shown in FIG. 7, the display panel 10 further includes a transparent region 201 and a pixel region 202. In a direction perpendicular to the plane where the display panel 10 is located, neither the thermal insulation structure 03 nor the first-type conductive layer M1 overlaps the transparent region 201. The light-emitting devices 02 are disposed in the pixel region 202.

Light transmittance of a portion of the display panel 10 corresponding to the transparent region 201 is greater than light transmittance of a portion of the display panel 10 corresponding to the pixel region 202.

In the embodiments of the present disclosure, for a transparent display panel, the thermal insulation structures 03 may be provided while avoiding the transparent region 201, so as to avoid affecting the overall transmittance of the panel, and at the same time reduce the influence of bonding laser irradiation.

In some embodiments, as shown in FIG. 7, the display panel 10 may include a compressed display region 041 and a regular display region 042, and gate driving circuits 051 may be disposed in the compressed display region 041. An area of the transparent region 201 located in the compressed display region 041 may be smaller than an area of the transparent regions 201 located in the regular display region 042, so that light transmittance corresponding to a portion of the display panel 10 in the regular display region 042 is greater than that in the compressed display region 041. In this case, the thermal insulation structures 03 may be disposed only in the compressed display region 041, and some of the thermal insulation structures 03 overlap the gate driving circuits 051. With this design, the gate driving circuits 051 can be shielded, while relatively high overall light transmittance of the regular display region 042 is ensured, improving the transparent display effect.

In some embodiments, as shown in FIG. 7, the display region 04 may further include a secondary compressed display region 043. Considering that the gate driving circuits 051 are disposed in the compressed display region 041, to relieve the distribution pressure of circuit structures in the compressed display region 041, pixel circuits 012 (not shown in FIG. 7) corresponding to the light-emitting devices 02 located in the compressed display region 041 may be arranged in the secondary compressed display region 043, so that a driving signal transmission structure 0121 can be used to provide the light-emitting driving current to the light-emitting devices 02 located in the compressed display region 041. The part of the driving signal transmission structure 0121 may be located in the first-type conductive layer M1 (for example, in the fifth metal layer 16).

Thermal insulation structures 03 may also be disposed in the secondary compressed display region 043, and some of the thermal insulation structures 03 overlap the driving signal transmission structure 0121 in a direction perpendicular to the plane where the display panel 10 is located. In addition, some of the thermal insulation structures 03 may also overlap the driving signal transmission structure 0121 in the compressed display region 041. The above design helps shield and protect the driving signal transmission structure 0121 by using the thermal insulation structures 03, preventing the damage to the integrity of the structure of the driving signal transmission structure 0121 caused by thermal expansion in a region where the driving signal transmission structure 0121 is located.

In addition, as shown in FIG. 7, to compare differences in conductive layer distribution densities corresponding to the regular display region 042, the compressed display region 041, and the secondary compressed display region 043, a third unit region 1013 may be selected in the regular display region 042, a fourth unit region 1014 may be selected in the compressed display region 041, and a fifth unit region 1015 may be selected in the secondary compressed display region 043. The third unit region 1013, the fourth unit region 1014, and the fifth unit region 1015 may have the same area (both may be S). Specifically, as shown in FIG. 7, orthographic projections corresponding to the third unit region 1013, the fourth unit region 1014, and the fifth unit region 1015 may each cover orthographic projections corresponding to six light-emitting devices 02.

It should be noted that when selecting the above unit regions, the selected unit regions may include transparent regions 201, that is, when calculating the metal distribution ratios of the unit regions, the area occupied by the transparent regions 201 must be taken into account. Specifically, the area occupied by the transparent regions 201 shall be included in the total area of the unit regions.

With reference to FIG. 5 and FIG. 7, the metal distribution ratios P corresponding to the third unit region 1013, the fourth unit region 1014, and the fifth unit region 1015 are calculated respectively with reference to the above calculation method of the metal distribution ratio. The metal distribution ratio corresponding to the third unit region 1013 is Pa, the metal distribution ratio corresponding to the fourth unit region 1014 is Pb, and the metal distribution ratio corresponding to the fifth unit region 1015 is Pc, where Pb>Pc>Pa.

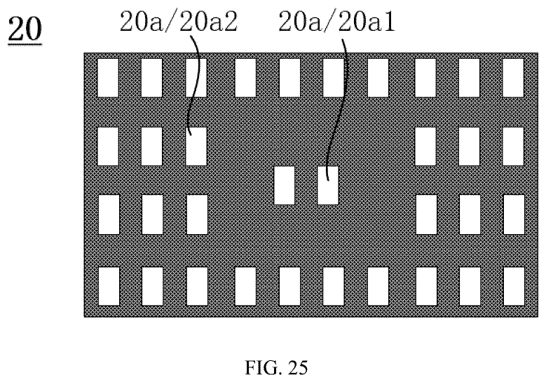

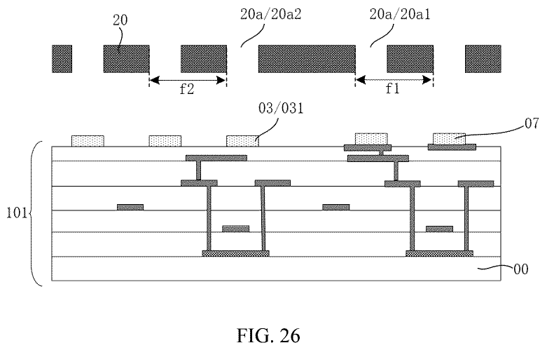

FIG. 25 is a top view of a partial structure of a first mask used in a panel manufacturing process according to an embodiment of the present disclosure, and FIG. 26 is a schematic diagram of a positional relationship between the first mask shown in FIG. 25 and a substrate during manufacturing of thermal insulation structures according to an embodiment of the present disclosure. For ease of understanding, FIG. 25 illustrates a distribution among partial evaporation openings of the first mask in a top view. FIG. 26 illustrates a relative position between partial structures of the first mask and partial structures of the substrate (a panel structure before completion of manufacturing of the thermal insulation structures) during manufacturing of the thermal insulation structures.

In some embodiments, considering that the connection structure 07 and the thermal insulation structure 03 may be disposed in the same layer and may have the same material, the connection structure 07 and the thermal insulation structure 03 may be manufactured in the same manufacturing step. With reference to FIG. 25 and FIG. 26, in this manufacturing step, a first mask 20 may be used to participate in manufacturing of the connection structure 07 and the thermal insulation structure 03. Specifically, the first mask 20 may be aligned with the substrate 101, and then a corresponding material may be supplied to evaporation openings 20a of the first mask 20, so as to form the connection structure 07 and the thermal insulation structure 03 by evaporation. The evaporation openings 20a may include first openings 20a1 and second openings 20a2. The first opening 20a1 may be an evaporation opening 20a corresponding to the connection structure 07, and the second opening 20a2 may be an evaporation opening 20a corresponding to the first-type thermal insulation structure 031 (the first-type thermal insulation structure 031 overlaps the gate driving circuit 051). A sum of a spacing between adjacent first openings 20a1 and a width of a single first opening 20a1 is a first dimension f1, and a sum of a spacing between adjacent second openings 20a2 and a width of a single second opening 20a2 is a second dimension f2, where f1=f2. With this design, manufacturing difficulty of the evaporation openings 20a corresponding to the first mask 20 can be effectively reduced, helping lower manufacturing costs.

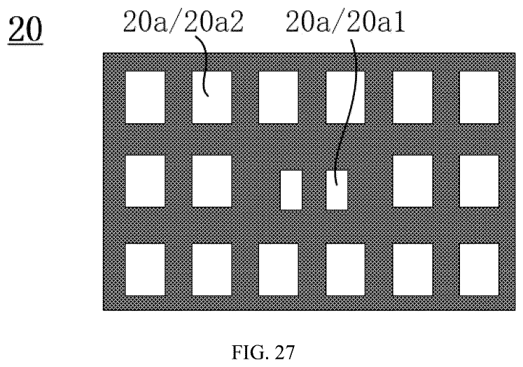

FIG. 27 is a top view of a partial structure of a first mask used in a panel manufacturing process according to an embodiment of the present disclosure. For ease of understanding, FIG. 27 illustrates a distribution among partial evaporation openings of the first mask in a top view.

In some embodiments, as shown in FIG. 27, the evaporation openings 20a may include first openings 20a1 and second openings 20a2. The first opening 20a1 may be an evaporation opening 20a corresponding to the connection structure 07, and the second opening 20a2 may be an evaporation opening 200a corresponding to the first-type thermal insulation structure 031 (the first-type thermal insulation structure 031 overlaps the gate driving circuit 051). An orthographic projection area of the second opening 20a2 may be larger than an orthographic projection area of the first opening 20a1. With this design, compared with the first opening 20a1 for evaporating the connection structure 07, the second opening 20a2 for evaporating the first-type thermal insulation structure 031 has a larger orthographic projection area, which helps achieve a larger orthographic projection area of the first-type thermal insulation structure 031 upon completion of evaporation, and facilitates a larger effective shielding area of the first-type thermal insulation structure 031 for the first-type conductive layer M1 therebelow, so as to shield the gate driving circuit 051 therebelow as much as possible.

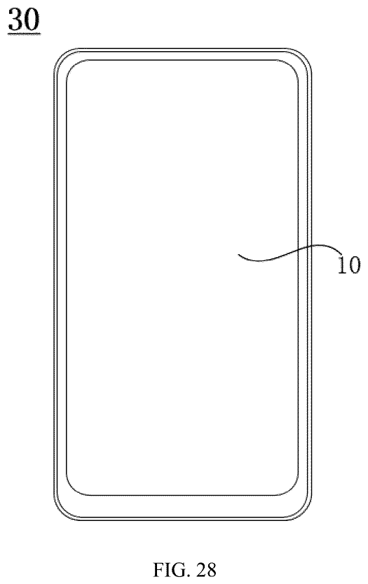

FIG. 28 is a schematic diagram of a display apparatus according to an embodiment of the present disclosure.

The present disclosure provides a display apparatus 30. As shown in FIG. 28, the display apparatus 30 includes the above display panel 10. The display apparatus 30 may be a mobile phone. In addition, the display apparatus 30 may also be an electronic device such as a computer or a television.

In the display apparatus 30 provided in the embodiments of the present disclosure, failures caused by bonding laser irradiation are effectively suppressed.

For the same and similar parts in each embodiment in this specification, reference may be made to each other. In particular, for the device embodiments and terminal embodiments, since they are basically similar to the method embodiments, the description is relatively simple, and for relevant parts, reference may be made to the description in the method embodiments.

What is claimed is:

1. A display panel, comprising an array substrate, and having a first region and a second region,
wherein the array substrate comprises: a substrate, a first-type conductive layer, and thermal insulation structures, wherein the first-type conductive layer comprises a first-type metal layer;
wherein a metal distribution ratio corresponding to the first region is P1, and a metal distribution ratio corresponding to the second region is P2, where P1>P2, the metal distribution ratio is a ratio of a projection area of a portion of the first-type metal layer corresponding to a unit region on the substrate to an area of the unit region; and
wherein the thermal insulation structures are located on a side of the first-type conductive layer away from the substrate and located in the first region, and the thermal insulation structures at least partially overlap the first-type metal layer in a direction perpendicular to a plane of the display panel.

2. The display panel according to claim 1, wherein P1−P2≥20%.

3. The display panel according to claim 1, wherein the first region comprises a first sub-region, and the first sub-region is located on a side of the second region adjacent to an edge of the display panel;
the display panel further comprises gate driving circuits located in the first sub-region, and at least part of a structure of the gate driving circuits is located in the first-type conductive layer; and
the thermal insulation structures comprise first-type thermal insulation structures, and an orthographic projection of the first-type thermal insulation structures on the substrate at least partially overlaps an orthographic projection of the gate driving circuits on the substrate.

4. The display panel according to claim 3, wherein the first sub-region comprises a first circuit region, the gate driving circuits are all located in the first circuit region, and the first circuit region is located within an orthographic projection of the first-type thermal insulation structures on the substrate; and
the display panel further comprises an electrostatic discharge structure, and the first-type thermal insulation structures are electrically connected to the electrostatic discharge structure.

5. The display panel according to claim 4, wherein the electrostatic discharge structure comprises a first portion and a pin, at least part of the first portion is located between a layer of the thermal insulation structures and the substrate, and at least part of the pin and the first-type thermal insulation structures are both located on the side of the first-type conductive layer away from the substrate, and the first-type thermal insulation structures are electrically connected to the first portion via the pin; or
wherein the electrostatic discharge structure comprises a first portion, and at least part of the first portion is located between a layer of the thermal insulation structures and the substrate, and the first-type thermal insulation structures are electrically connected to the first portion through a via hole.

6. The display panel according to claim 5, wherein the electrostatic discharge structure further comprises a second portion, a layer of the second portion is between the layer of the thermal insulation structures and the substrate, and the first portion and the second portion are disposed in different layers; and
the first-type thermal insulation structures are electrically connected to the first portion through a first via hole, and the first-type thermal insulation structures are electrically connected to the second portion through a second via hole.

7. The display panel according to claim 1, wherein an aspect ratio m of an orthographic projection of one of the thermal insulation structures on the substrate is less than or equal to 2, and orthographic projections corresponding to the thermal insulation structures are arranged in a multi-row, multi-column array; or
wherein an aspect ratio m of an orthographic projection of one of the thermal insulation structures on the substrate is greater than 2, the one thermal insulation structure is at least partially located in a first sub-region and has an orthographic projection extending along a first direction; and the first region comprises the first sub-region located on a side of the second region adjacent to an edge of the display panel, and the first direction is a direction from the first sub-region toward the second region.

8. The display panel according to claim 7, wherein the thermal insulation structures comprise second-type thermal insulation structures, an aspect ratio m of an orthographic projection of one of the second-type thermal insulation structures on the substrate is greater than 2, and the one second-type thermal insulation structure is located in the first sub-region and has an orthographic projection extending along the first direction;
the array substrate further comprises pixel electrodes, a layer of the pixel electrodes is on the side of the first-type conductive layer away from the substrate, the pixel electrodes are electrically connected to light-emitting devices, and the pixel electrodes overlap the second region and do not overlap the first sub-region in the direction perpendicular to the plane of the display panel; and
a width of an orthographic projection of the one second-type thermal insulation structure on the substrate gradually increases along the first direction.

9. The display panel according to claim 8, wherein the one second-type thermal insulation structure comprises a first thermal insulation portion and a second thermal insulation portion, and the first thermal insulation portion is located on a side of the second thermal insulation portion adjacent to the second region along the first direction; and
a thickness of the first thermal insulation portion is greater than a thickness of the second thermal insulation portion.

10. The display panel according to claim 1, wherein the first region comprises a second sub-region and a third sub-region, and the second sub-region is located between the third sub-region and the second region;
the thermal insulation structures comprise third-type thermal insulation structures and fourth-type thermal insulation structures, the third-type thermal insulation structures are located in the second sub-region, and the fourth-type thermal insulation structures are located in the third sub-region; and
in the second sub-region, a spacing between some adjacent third-type thermal insulation structures is w1, and in the third sub-region, a spacing between some adjacent fourth-type thermal insulation structures is w2, where w1<w2.

11. The display panel according to claim 10, wherein a thickness of one of the third-type thermal insulation structures is greater than a thickness of one of the fourth-type thermal insulation structures; and/or
wherein an orthographic projection area of one of the third-type thermal insulation structures on the substrate is greater than an orthographic projection area of one of the fourth-type thermal insulation structures on the substrate.

12. The display panel according to claim 10, wherein a metal distribution ratio P12 corresponding to the second sub-region is greater than a metal distribution ratio P13 corresponding to the third sub-region.

13. The display panel according to claim 12, wherein the second sub-region is adjacent to the third sub-region, and the metal distribution ratio P12 corresponding to the second sub-region and the metal distribution ratio P13 corresponding to the third sub-region satisfy: P12−P13≥10%; and
the third sub-region comprises a first zone and a second zone, and the second zone is located on a side of the first zone adjacent to the second sub-region; in the first zone, a spacing between some adjacent fourth-type thermal insulation structures is w21, and in the second zone, a spacing between some adjacent fourth-type thermal insulation structures is w22, where w1<w22<w21.

14. The display panel according to claim 13, wherein the second sub-region comprises a third zone and a fourth zone, and the third zone is located on a side of the fourth zone adjacent to the third sub-region; and in the third zone, a spacing between some adjacent third-type thermal insulation structures is w11, and in the fourth zone, a spacing between some adjacent third-type thermal insulation structures is w12, where w12<w11<w22.

15. The display panel according to claim 1, wherein the array substrate further comprises pixel electrodes, a layer of the pixel electrodes is on the side of the first-type conductive layer away from the substrate, and the pixel electrodes are electrically connected to light-emitting devices via a connection structure; and
the thermal insulation structures and the connection structure are spaced apart from each other.

16. The display panel according to claim 15, wherein the thermal insulation structures and the connection structure are located in a same layer; or
wherein the display panel further comprises a protruding structure comprising an electrical insulating material, wherein in a direction parallel to the plane of the display panel, the protruding structure is located between the thermal insulation structures and the connection structure.

17. The display panel according to claim 16, wherein a height h1 of the protruding structure is greater than a thickness h2 of one of the thermal insulation structures in the direction perpendicular to the plane of the display panel.

18. The display panel according to claim 1, wherein the array substrate further comprises pixel electrodes, a layer of the pixel electrodes is on the side of the first-type conductive layer away from the substrate, and the pixel electrodes are electrically connected to light-emitting devices via a connection structure; and
materials of the thermal insulation structures and the connection structure comprise metallic tin.

19. The display panel according to claim 1, further comprising:
a transparent region and a pixel region, wherein the thermal insulation structures and the first-type conductive layer do not overlap the transparent region in the direction perpendicular to the plane of the display panel, and light-emitting devices are disposed in the pixel region; and
wherein light transmittance of a portion of the display panel corresponding to the transparent region is greater than light transmittance of a portion of the display panel corresponding to the pixel region.

20. A display apparatus, comprising a display panel, wherein the display panel comprises an array substrate, and has a first region and a second region,
wherein the array substrate comprises: a substrate, a first-type conductive layer, and thermal insulation structures, wherein the first-type conductive layer comprises a first-type metal layer;
wherein a metal distribution ratio corresponding to the first region is P1, and a metal distribution ratio corresponding to the second region is P2, where P1>P2, the metal distribution ratio is a ratio of a projection area of a portion of the first-type metal layer corresponding to a unit region on the substrate to an area of the unit region; and
wherein the thermal insulation structures are located on a side of the first-type conductive layer away from the substrate and located in the first region, and the thermal insulation structures at least partially overlap the first-type metal layer in a direction perpendicular to a plane of the display panel.
